(19) United States
(12) Patent Application Publication
(10) Pub. No.: US 2009/0020886 A1
(43) Pub. Date: Jan. 22, 2009

(54) SEMICONDUCTOR DEVICE AND METHOD OF FABRICATING THE SAME

(76) Inventor: Joon-Ku Yoon, Suwon-Si (KR)

Correspondence Address: SHERR & VAUGHN, PLLC, 620 HERNDON PARKWAY, SUITE 200, HERNDON, VA, 20170, US

(21) Appl. No.: 12/172,219

(22) Filed: Jul. 12, 2008

(30) Foreign Application Priority Data
Jul. 20, 2007 (KR) 10-2007-0074956

(51) Int. Cl. H01L 23/52; H01L 21/00

(52) U.S. Cl. 257/777; 438/109; 257/E23.141; 257/E21.001

(57) ABSTRACT

Embodiments relate to a semiconductor device, which adopts no wiring or contact for electric connection of a plurality of chips, achieving improved fabrication efficiency and reducing fabrication costs thereof, and a method of fabricating the same. A System In Package (SIP) semiconductor device includes a plurality of first and second semiconductor chips each having a predetermined internal circuit and being bonded opposite each other, wherein the first and second semiconductor chips include, respectively, trenches formed in the centers thereof to have a predetermined depth. First and second metal electrodes are formed in inner bottom surfaces of the respective trenches to apply current to the respective internal circuits of the first and second semiconductor chips. A liquid-phase conductive material fills in a predetermined volume of the trenches for selective conduction of the first and second metal electrodes. A plurality of bonding portions formed in surfaces of the first and second semiconductor chips to correspond to each other for coupling of the first and second semiconductor chips.

The present application claims priority under 35 U.S.C. 119 to Korean Patent Application No. 10-2007-0074956 (filed on Jul. 26, 2007), which is hereby incorporated by reference in its entirety.

### BACKGROUND

In the related art, the use of semiconductor devices has been limited to specific fields. However, with the rapid progress being made in the so-called information society, with the development of Internet and communication technologies, the application range of semiconductor devices is gradually increasing. Semiconductor devices have been applied in mobile products, including cellular phones and PDAs, display apparatuses, portable image/sound reproducing apparatuses, and a variety of electronic products used in the home.

To apply semiconductor devices to various products as enumerated above, the devices should be multifunctional. In particular, mobile products, such as portable communication and image/sound reproducing apparatuses, etc., must be small in size, multifunctional and high-speed. To meet these needs, a so-called System In Package (SIP), has been developed. A plurality of identical or different types of chips may be vertically stacked on a single wafer and electrically interconnected to constitute a single package.

In contrast to a related single-chip package, when using an SIP with vertically stacked chips, identical chips may be stacked to increase memory density. Memory chips and/or logic chips may be stacked in two layers to provide a multifunctional package. Accordingly, compared to related semiconductor devices in which chips are spread out and separated by function, the SIP can achieve a reduction in size and an increase in functionality.

FIG. 1 is a sectional view illustrating a related System In Package (SIP) semiconductor device. Referring to FIG. 1, the related SIP semiconductor device 10 includes a plurality of identical or different types of chips 12a, 12b, 12c and 12d disposed on upper and lower surfaces of a printed circuit board (PCB) 11.

The plurality of chips 12a, 12b and 12c, disposed on the upper surface of the printed circuit board 11, are electrically connected with the printed circuit board 11 via bonding wires 13. The chip 12d, disposed on the lower surface of the printed circuit board 11, is electrically connected with the printed circuit board 11 via contacts 14. Here, adhesive layers 15 are interposed between the plurality of neighboring chips 12a, 12b and 12c, to define a vertical stacking configuration.

Molding resin 16 is formed over the upper surface of the printed circuit board 11, to seal the plurality of chips 12a, 12b and 12c and the bonding wires 13. Under-fill resin 17 is formed between the lower surface of the printed circuit board 11 and the chip 12d, to seal the lower surface of the printed circuit board 11 and the contacts 14. Solder connections 18 are formed over the lower surface of the printed circuit board 11, to connect the SIP semiconductor device 10 with an external station.

The related SIP semiconductor device 10 is configured such that the plurality of chips 12a, 12b, 12c and 12d are connected with the printed circuit board 11 via the bonding wires 13 or the contacts 14. Accordingly, interconnection between the chips and the printed circuit board requires relatively long connectors, resulting in a limit in the improvement of system performance. Furthermore, such an interconnection configuration using the bonding wires 13 limits a reduction in the size of the SIP semiconductor device 10.

Although a plurality of chips may be connected using vias perforated through the chips, this configuration has the disadvantages of requiring additional processes for formation of the vias and of complicating the overall configuration of a resulting semiconductor device due to arrangement of plural wirings. Moreover, semiconductor devices having a reduced size suffer from instability in configuration.

Thus, when connecting a plurality of chips with a printed circuit board using bonding wires or contacts, the resulting related SIP semiconductor devices have limited improvement of system performance. Size reduction is limited by relatively long connectors for interconnection between the chips and the printed circuit board. When connecting a plurality of chips using vias perforated through the chips, the resulting related SIP semiconductor devices have the disadvantages of requiring additional processes for formation of the vias and of complicated device configuration because of the arrangement of plural wirings. In particular, small-size related SIP semiconductor devices suffer from instability in configuration.

### SUMMARY

Embodiments relate to a method of fabricating a semiconductor device, and more particularly, to a System In Package (SIP) semiconductor device and a method of fabricating the same. Embodiments relate to a semiconductor device, which adopts no wiring or contact for electric connection of a plurality of chips, achieving improved fabrication efficiency and reducing fabrication costs thereof, and a method of fabricating the same.

A System In Package (SIP) semiconductor device includes a plurality of first and second semiconductor chips each having a predetermined internal circuit and being bonded opposite each other, wherein the first and second semiconductor chips include, respectively, trenches formed in the centers thereof to have a predetermined depth. First and second metal electrodes are formed in inner bottom surfaces of the respective trenches to apply current to the respective internal circuits of the first and second semiconductor chips. A liquid-phase conductive material fills in a predetermined volume of the trenches for selective conduction of the first and second metal electrodes. A plurality of bonding portions formed in surfaces of the first and second semiconductor chips to correspond to each other for coupling of the first and second semiconductor chips.

The liquid-phase conductive material may be mercury. The liquid-phase conductive material may immerse the first and second metal electrodes when the SIP semiconductor device is oriented in a first direction, to electrically connect the first and second metal electrodes with each other. The liquid-phase conductive material may move downward in the trenches due to gravity when the SIP semiconductor device is oriented in a second direction, to electrically disconnect the first and second metal electrodes. The bonding portions may be gap-filled with a metal solder material or a non-metal adhesive material. A metal film may be formed at an inner wall of each bonding portion.

Embodiments relate to a method of fabricating a System In Package (SIP) semiconductor device including providing first and second semiconductor chips each having an internal circuit. First and second trenches are formed in the centers of the first and second semiconductor chips, respectively, to have a depth of 10μ to 100μ. First and second metal electrodes are formed over bottom surfaces of the respective trenches, to apply current to the respective predetermined internal circuits.; A liquid-phase conductive material is formed in at least one of the plurality of first and second trenches up to a predetermined volume. The first and second semiconductor chips are stacked opposite each other. The first and second semiconductor chips are coupled to each other as a plurality of bonding portions, which are formed in surfaces of the first and second semiconductor chips to correspond to each other, are gap-filled with an adhesive material.

In the above-described method, the liquid-phase conductive material may be mercury. In the above-described method, the bonding portions may be gap-filled with a metal solder material or a non-metal adhesive material. The method of fabricating the SIP semiconductor device may further include forming a metal film at an inner wall of each bonding portion.

### DRAWINGS

FIG. 1 is a sectional view illustrating a related System In Package (SIP) semiconductor device.

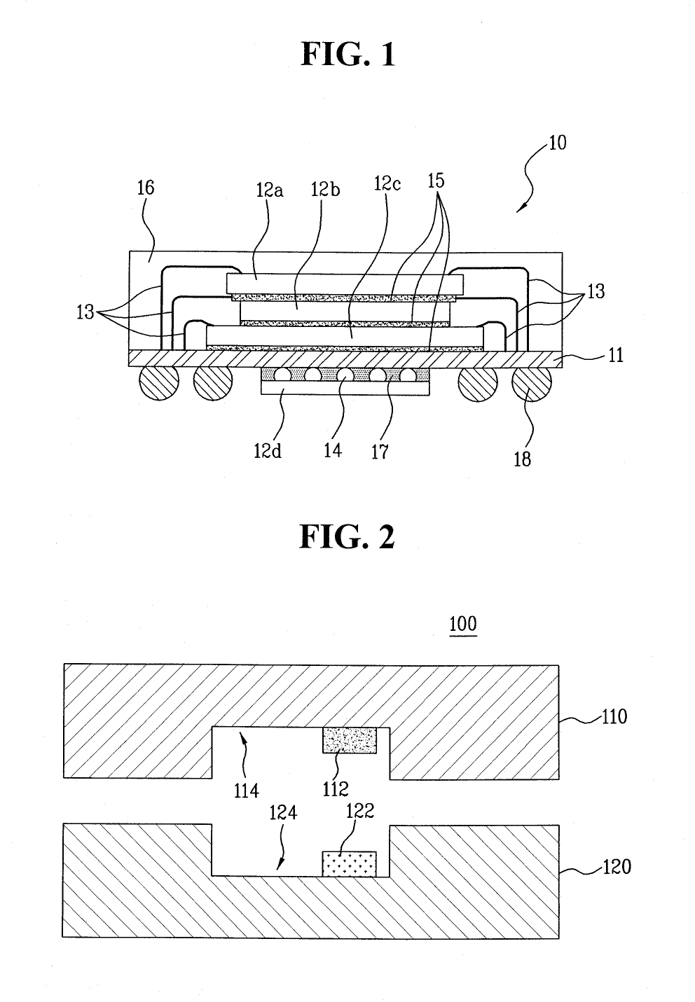

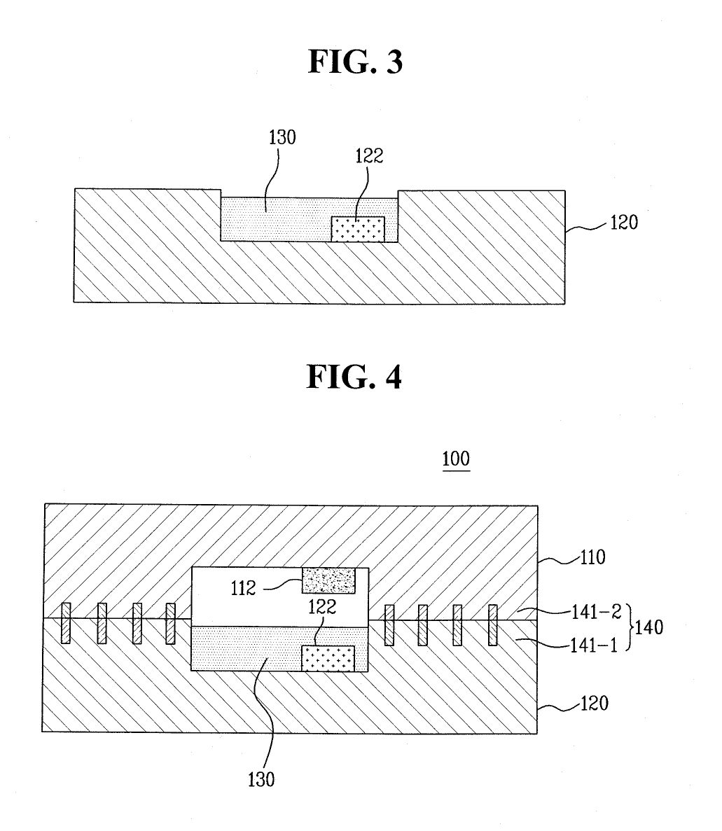

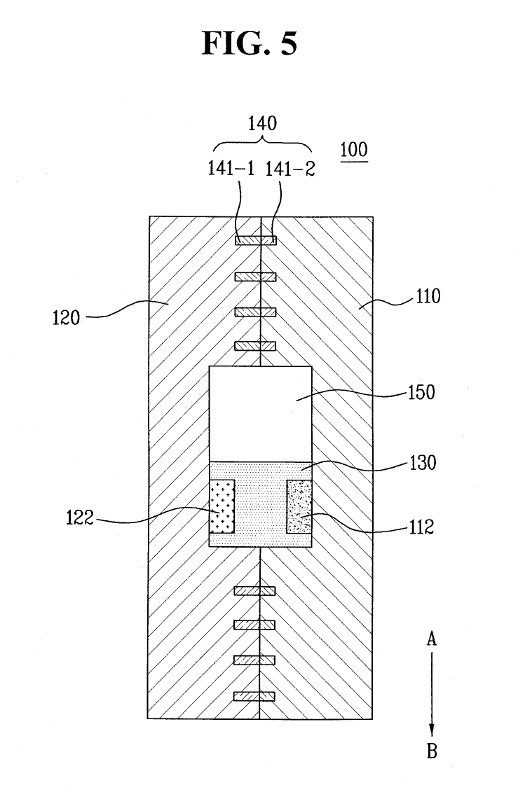

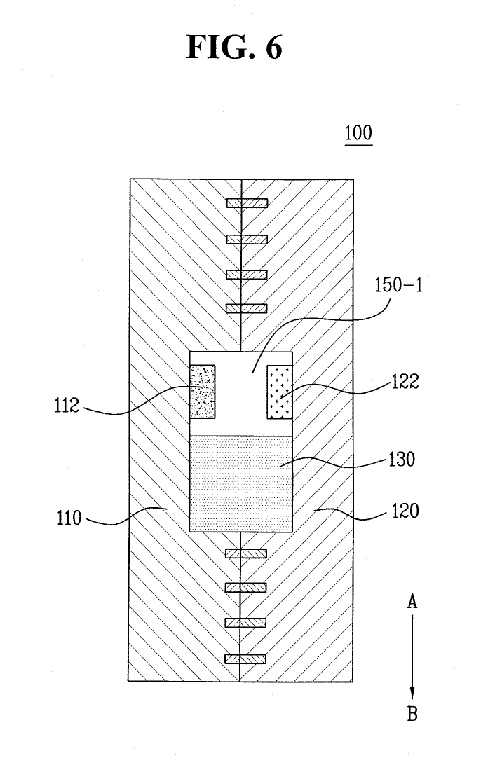

Example FIG. 2 is a sectional view illustrating a System In Package (SIP) semiconductor device in accordance with embodiments.

Example FIGS. 3 and 4 are sectional views illustrating sequential processes of fabricating a SIP semiconductor device in accordance with embodiments.

Example FIGS. 5 and 6 are views illustrating an operating method of a SIP semiconductor device in accordance with embodiments.

### DESCRIPTION

Example FIG. 2 is a sectional view illustrating a System In Package (SIP) semiconductor device in accordance with embodiments. Referring to example FIG. 2, the SIP semiconductor device 100 in accordance with embodiments includes a plurality of identical or different types of semiconductor chips 110 and 120 disposed on a printed circuit board (PCB), the plurality of semiconductor chips 110 and 120 being stacked opposite each other.

The plurality of semiconductor chips 110 and 120, as shown in example FIG. 4, include bonding portions 141-1 and 141-2 corresponding to each other, respectively. The corresponding bonding portions 141-1 and 141-2 may be gap-filled with an adhesive material, whereby the corresponding bonding portions 141-1 and 141-2 are bonded to each other by the gap-filled adhesive material, forming bonding coupling portions 140. The plurality of semiconductor chips 110 and 120 can be coupled to each other via the bonding coupling portions 140.

The plurality of semiconductor chips 110 and 120 have trenches 114 and 124, each having a depth of 10μ to 100μ, respectively. In turn, metal electrodes 112 and 122 are formed in the trenches 114 and 124, respectively, to apply current to internal circuits of the respective semiconductor chips 110 and 120.

The trenches 114 and 124 formed in the respective semiconductor chips 110 and 120, as shown in example FIGS. 3 and 4, are filled with a liquid-phase conductive material 130, to electrically connect the plurality of metal electrodes 112 and 122 to each other. In this case, the liquid-phase conductive material 130 may fill the respective trenches 114 and 124 only to a predetermined height, leaving a remaining space, rather than completely filling the trenches 114 and 124. The plurality of chips 110 and 120 may be electrically connected with the printed circuit board via bonding wires or contacts.

Example FIGS. 3 and 4 are sectional views illustrating sequential processes of fabricating the SIP semiconductor device in accordance with embodiments. A method of fabricating the SIP semiconductor device 100 in accordance with embodiments will be described with reference to example FIGS. 2 to 4. Here, the important feature of embodiments relates to a connecting configuration between the plurality of semiconductor chips 110 and 120 and bonding of the plurality of semiconductor chips 110 and 120 and therefore, other general configurations of the SIP semiconductor device and fabrication processes thereof, which are outside the scope of embodiments, will not be described.

First, the first semiconductor chip 120, in which a memory or non-memory circuit is formed, is prepared on a wafer via a semiconductor fabrication process. As described above, the trench 124 having a depth of 10μ to 100μ is formed in the center of the first semiconductor chip 120. Then, the metal electrode 122 is formed over an inner bottom surface of the trench 124. The metal electrode 122 serves to apply current to the circuit formed in the first semiconductor chip 120.

Next, the trench 124 of the first semiconductor chip 120 is filled with the liquid-phase conductive material 130. In this case, all types of liquid-phase materials capable of conducting current are applicable as the liquid-phase conductive material 130. For example, the liquid-phase conductive material may be mercury (Hg). Mercury is a liquid at room temperature and is a non-volatile material having excellent malleability and ductility thereof. Therefore, when mercury is used as the liquid-phase conductive material 130, it can be easily applied to fabrication processes. In addition, since mercury has a substantially constant coefficient of thermal expansion, after mercury fills the trench 124, variation in the volume of mercury due to heat generated during operation of the semiconductor device can be expected and an appropriate amount of the liquid-phase conductive material can be easily calculated. Thus, stable operation of the semiconductor device after filling of the liquid-phase conductive material can be accomplished.

Subsequently, as shown in example FIGS. 2 and 4, the second semiconductor chip 110 is stacked opposite the first semiconductor chip 120. In the same manner as the first semiconductor chip 120, the trench 114 having a depth of 10μ to 100μ is formed in the center of the second semiconductor chip 110, and in turn, the metal electrode 112 is formed in an inner bottom surface of the trench 114 to apply current to a circuit formed in the second semiconductor chip 110.

Thereafter, the first semiconductor chip 120 and the second semiconductor chip 110 are connected to each other via a plurality of bonding coupling portions 140. More specifically, first, the first bonding portions 141-1 are formed in the first semiconductor chip 120 and the second bonding portions 141-2 are formed in the second semiconductor chip 110. Here, the first and second bonding portions 141-1 and 141-2 may take the form of via holes, and may be arranged to correspond to each other.

The first bonding portions 141-1 and the second bonding portions 141-2 are gap-filled with an adhesive material. The first and second bonding portions 141-1 and 141-2 are bonded to each other by the gap-filled adhesive material, forming the bonding coupling portions 140. With the bonding coupling portions 140, the second semiconductor chip 110 can be coupled to and stacked on the first semiconductor chip 120. Also, with the coupling of the first bonding portions 141-1 and the second bonding portions 141-2, it is possible to prevent leakage of the liquid-phase conductive material 130 contained in the trenches 114 and 124.

Here, the adhesive material can be any general metal solder material or non-metal adhesive material capable of bonding metals and non-metals. When the plurality of semiconductor chips 110 and 120 are coupled to each other by use of metal solder materials, a thin metal film may be formed at inner walls of the bonding portions 141-1 and 141-2, to improve an adhesive force of the adhesive material.

Example FIGS. 5 and 6 are views illustrating an operating method of the SIP semiconductor device in accordance with embodiments. The SIP semiconductor device 100 in accordance with embodiments can selectively achieve electric connection between the plurality of chips, for example, between the first semiconductor chip 120 and the second semiconductor chip 110 by use of the liquid-phase conductive material 130 filled in the SIP semiconductor device 100.

In the above-described SIP semiconductor device 100, a trench space 150, in which the liquid-phase conductive material 130 is filled, can be provided by bonding of the first semiconductor chip 120 and the second semiconductor chip 110. The metal electrode 122 (hereinafter, referred to as a “first metal electrode”) of the first semiconductor chip 120 and the metal electrode 112 (hereinafter, referred to as a “second metal electrode”) of the second semiconductor chip 110 are formed in the trench space 150. The liquid-phase conductive material 130 has fluidity, and fills a predetermined portion of the trench space 150 in which the first metal electrode 122 and the second metal electrode 112 are formed.

First, as shown in example FIG. 5, the case where the SIP semiconductor device 100 is positioned in a first direction will be described. With the first directional positioning, the liquid-phase conductive material 130 within the trench space 150 moves to immerse the first metal electrode 122 and the second metal electrode 122, thereby allowing the first semiconductor chip 120 and the second semiconductor chip 110 to be electrically connected to each other. Next, as shown in example FIG. 6, the case where the SIP semiconductor device 100 is positioned in a second direction will be described. In this case, the direction from A to B is the direction of the force of gravity.

With the second directional positioning, the first and second metal electrodes 122 and 112 are located in an air space 150-1 in the upper region of the trench space 150, whereas the liquid-phase conductive material 130 is located in the lower region of the trench space 150 due to gravity. Thus, there exists no conductive material capable of conducting current between the two metal electrodes 112 and 122, such that the two metal electrodes 112 and 122 are not electrically connected to each other.

As apparent from the above description, according to the semiconductor device and the method of fabricating the same in accordance with embodiments, a trench is formed within a plurality of semiconductor chips and the plurality of semiconductor chips are electrically connected with each other by use of a liquid-phase conductive material filled in a predetermined volume of the trench. This electric connection of the plurality of semiconductor chips according to embodiments eliminates separate conductive lines or contacts which have been used in the related art to electrically connect a plurality of semiconductor chips. This simplifies the overall fabrication of the semiconductor device, resulting in improved fabrication efficiency of the semiconductor device. Further, according to embodiments, the plurality of semiconductor chips are coupled to each other via bonding portions without adhesive layers which have been used in the related art, resulting in improved fabrication efficiency and reduced fabrication costs.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a first semiconductor chip and a second semiconductor chip each having an internal circuit, the first and second semiconductor chips being bonded opposite each other, wherein each of the first and second semiconductor chips includes:
a trench formed to correspond to a trench of the other semiconductor chip;
a metal electrode formed in an inner bottom surface of the trench;
a liquid-phase conductive material filled in the trench; and
a bonding portion formed in a chip surface to correspond to a bonding portion of the other semiconductor chip, the first and second semiconductor chips being bonded to each other via the corresponding bonding portions,
wherein the liquid-phase conductive material fills a trench space defined as the corresponding trenches of the first semiconductor chip and the second semiconductor chip are bonded to each other.

2. The apparatus of claim 1, wherein the corresponding trenches are formed in the centers of the first semiconductor chip and the second semiconductor chip, respectively, to have a depth of approximately 10μ to 100μ.

3. The apparatus of claim 1, wherein the liquid-phase conductive material is mercury.

4. The apparatus of claim 1, wherein the bonding portions are formed of a metal solder material.

5. The apparatus of claim 1, wherein the bonding portions are formed of a non-metal adhesive material.

6. The apparatus of claim 4, wherein each bonding portion is formed, at an inner wall thereof, with a metal film, for reinforcement of an adhesive force.

7. The apparatus of claim 1, wherein the liquid-phase conductive material has fluidity.

8. The apparatus of claim 1, wherein the liquid-phase conductive material fills the trench space to occupy a partial inner region of the trench space.

9. The apparatus of claim 1, wherein the liquid-phase conductive material, filled in the trench space, moves to immerse both the metal electrode of the first semiconductor chip and the metal electrode of the second semiconductor chip when the apparatus is oriented in a first direction.

10. The apparatus of claim 9, wherein the liquid-phase conductive material, filled in the trench space, moves so as not to immerse both the metal electrode of the first semiconductor chip and the metal electrode of the second semiconductor chip when the apparatus is oriented in a second direction.

11. A method comprising:
providing a first semiconductor chip and a second semiconductor chip each having an internal circuit;
forming trenches in the first semiconductor chip and the second semiconductor chip, respectively, to correspond to each other;
forming metal electrodes over bottom surfaces of the respective trenches, to correspond to each other;
filling a liquid-phase conductive material in at least one of the trenches; and
bonding the first semiconductor chip and the second semiconductor chip to each other such that the trenches correspond to each other and the metal electrodes correspond to each other.

12. The method of claim 11, comprising forming the trenches in the centers of the first semiconductor chip and the second semiconductor chip, respectively, to have a depth of 1082 to 100μ.

13. The method of claim 11, comprising forming the metal electrodes to be connected with the respective internal circuits.

14. The method of claim 11, comprising filling at least one of the trenches with mercury.

15. The method of claim 11, comprising bonding the first semiconductor chip and the second semiconductor chip to each other with a metal solder material.

16. The method of claim 11, comprising bonding the first semiconductor chip and the second semiconductor chip to each other with a non-metal adhesive material.

17. The method of claim 11, comprising filling the liquid-phase conductive material into a partial region of a trench space defined as the corresponding trenches are bonded to each other and the corresponding metal electrodes are bonded to each other.

18. The method of claim 15, comprising: prior to bonding the first semiconductor chip and the second semiconductor chip to each other with a metal solder material, forming a metal film at a bonding interface surfaces between the first semiconductor chip and the second semiconductor chip.

19. The method of claim 11, comprising filling at least one of the trenches with mercury sufficient to immerse both the metal electrode of the first semiconductor chip and the metal electrode of the second semiconductor chip when a resulting structure is oriented in a first direction.

20. The method of claim 19, comprising leaving space in the trenches sufficient to so as not to immerse in mercury both the metal electrode of the first semiconductor chip and the metal electrode of the second semiconductor chip when the resulting structure is oriented in a second direction.
